(19) United States
(12) Patent Application Publication
(10) Pub. No.: US 2005/0039946 A1
(43) Pub. Date: Feb. 24, 2005

(54) Electronic circuit unit and method of manufacturing same

(75) Inventor: Kazuhiro Nakao, Fukushima-ken (JP)

Correspondence Address: BRINKS HOFER GILSON & LIONE, P.O. BOX 10395, CHICAGO, IL, 60610, US

(73) Assignee: ALPS ELECTRIC CO., LTD.

(21) Appl. No.: 10/912,633

(22) Filed: Aug. 5, 2004

(30) Foreign Application Priority Data
Aug. 20, 2003 (JP) 2003-296628

(51) Int. Cl. H05K 1/11

(52) U.S. Cl. 174/255; 174/264

(57) ABSTRACT

An electronic circuit unit includes a circuit substrate having electronic components mounted on the component mounting side thereof, an insulating layer which is layered and crimped onto the component mounting side so as to cover a wiring pattern and electronic components, and a shield layer, made of a metal foil, which is formed on the insulating layer. Since the shield layer conducts with a grounding pattern via columnar conductive sections provided at the four corners, a shield case made of a metal plate is not required. A large number of electronic circuit units is obtained by dividing a large-area laminate, and each columnar conductive section is formed by dividing a through hole filled with a conductive material into four portions. The insulating layer is formed by heat-crimping a semi-cured prepreg material.

### BACKGROUND OF THE INVENTION

1. Field of the Invention

The present invention relates to a small electronic circuit unit, such as a high-frequency unit, in which electronic components mounted on a circuit substrate need to be shielded, and to a method of manufacturing an electronic circuit unit, such that a large number of this type of electronic circuit units can be obtained by dividing a large-area substrate into a lattice shape.

2. Description of the Related Art

There has hitherto been a known technology in which a large number of electronic circuit units is obtained by dividing for each component mounting area a large-area substrate into a lattice shape. A manufacturing method has been proposed in which, when manufacturing electronic circuit units in which electronic components provided in a component mounting area need to be shielded, shield cases are collectively mounted in individual component mounting areas of a large-area substrate before the dividing step, and thus the operation efficiency is improved. FIG. 12 is a perspective view of an electronic circuit unit manufactured by such conventional technology. FIG. 13 is a process chart of manufacturing the electronic circuit unit. The related art will now be described below with reference to these figures.

An electronic circuit unit 1 shown in FIG. 12 is, for example, a voltage-controlled oscillator (VCO). The electronic circuit unit 1 includes a circuit substrate 2 which is rectangular in plan view, having mounted on one side thereof (the component mounting side 2a) electronic components 3 such as chip capacitors and semiconductors (see FIG. 13), and a shield case 4 mounted on the circuit substrate 2 in such a manner as to cover the electronic components 3. A wiring pattern (not shown) is formed on the component mounting side 2a of the circuit substrate 2. The electronic components 3 are soldered to the land portion of the wiring pattern, and also, side electrodes, such as input/output terminals, which extend from the wiring pattern are formed on the side walls of recessed grooves 5 positioned at the four corners on the side surface of the circuit substrate 2. Furthermore, recessed grooves 6 into which foot pieces 4a of the shield case 4 are inserted for soldering are formed at a plurality of portions on the side surfaces of the circuit substrate 2. The shield case 4 is formed by bending a metal plate into a box shape. The shield case 4 has side wall sections 4b which each extend to the circuit substrate 2 side from the four sides of a rectangular ceiling plate section opposing the component mounting side 2a of the circuit substrate 2, and the foot pieces 4a are protrusively provided at the front end of each side wall section 4b. As will be described later, the circuit substrate 2 is such that a large-area substrate after the electronic components are mounted is divided by a dicing blade. In this dividing step, a clearance for avoiding contact is needed between the dicing blade and the side wall section 4b of the shield case 4. Therefore, each side wall section 4b is arranged inside the side surface of the circuit substrate 2.

When the electronic circuit unit 1 configured in this manner is to be manufactured, first, a large-area substrate 10 on which are formed wiring patterns, grounding patterns, etc., corresponding to a large number of electronic circuit units 1 is prepared. One side of this large-area substrate 10 is divided into a large number of component mounting areas by boundary lines extending vertically and horizontally, and through holes which correspond to the recessed grooves 5 and 6 are formed in each boundary line. The land portion of the wiring pattern formed in each component mounting area is coated with cream solder. After the electronic components 3 are placed on the cream solder, the large-area substrate 10 is conveyed to a reflow furnace, and the electronic components 3 are soldered. Next, cream solder is coated from the bottom side of the large-area substrate 10 to the through hole corresponding to the recessed groove 6, and thereafter, the foot pieces 4a of the shield case 4 arranged so as to cover the electronic components 3 are inserted into the through hole. In this state, by conveying the large-area substrate 10 to the reflow furnace and soldering the foot pieces 4a, each shield case 4 is fixed to the large-area substrate 10 in a state in which the shield case 4 is made to conduct with the grounding pattern. Eventually, as shown in FIG. 13, the large-area substrate 10 is cut along the boundary lines by a dicing blade 11, and the large-area substrate 10 is subdivided into individual circuit substrates 2 corresponding to each component mounting area. Thus, a large number of electronic circuit units 1 with the shield case 4 can be obtained. At the stage where individual electronic circuit units 1 become electrically independent, frequency adjustment, performance testing, and the like are performed.

In the above-described conventional technology, the side wall section 4b of the shield case 4 of the electronic circuit unit 1 requires a clearance C1 for avoiding contact in a portion adjoining with the electronic components 3 mounted nearby and also requires a clearance C2 for avoiding contact with the dicing blade 11 in the dividing step. These clearances C1 and C2 must have values such that the variations of the dimensions of the shield case 4 formed by bending a metal plate can be accomodated. For this reason, as shown in FIG. 13, between the electronic components 3 mounted in the outermost peripheral portion of the electronic circuit unit 1 and the side surface of the circuit substrate 2, a slightly wider dimension A is required such that the plate thickness of the side wall section 4b is added to the clearances C1 and C2. Conventionally, the fact that the outer dimensions of the circuit substrate 2 must be set so as to allow for such dimension A is a factor which hinders size reduction of the electronic circuit unit 1. Furthermore, the ceiling plate section of the shield case 4 also requires a predetermined clearance C3 in a portion adjoining with the electronic components 3. Therefore, in the conventional electronic circuit unit 1, the overall height dimension must be set so as to allow for dimension B such that the clearance C3 and the plate thickness of the ceiling plate section are added above the electronic components 3. This dimension B is a hindrance when a lower profile is to be achieved.

### SUMMARY OF THE INVENTION

The present invention has been made in view of such circumstances of the conventional technology. A first object of the present invention is to provide an electronic circuit unit for which a smaller size and a lower profile can be easily achieved. A second object of the present invention is to provide a manufacturing method capable of efficiently manufacturing an electronic circuit unit for which a smaller size and a lower profile can be easily achieved.

To achieve the first object, in one aspect, the present invention provides an electronic circuit unit including: a circuit substrate having electronic components mounted on one side thereof on which a wiring pattern is formed; an insulating layer which is layered and crimped onto the one side of the circuit substrate so as to cover the wiring pattern and the electronic components; and a shield layer, formed of a conductive material, which is formed on the insulating layer, wherein a grounding pattern formed on a side opposite to the one side of the circuit substrate and the shield layer are made to conduct with each other via a columnar conductive section provided on the side wall of a laminate formed in such a manner that the circuit substrate and the insulating layer are formed integrally.

In the electronic circuit unit configured in this manner, a shield layer formed of a metal foil, etc., is provided on an insulating layer which is layered and crimped onto the component mounting side of a circuit substrate, and this shield layer is made to conduct with a grounding pattern. Therefore, the electronic components mounted on the component mounting side can be shielded by the shield layer, and thus a shield case made of a metal plate is not necessary. As a result, a wider clearance need not be provided in the periphery of the electronic components on the circuit substrate for the purpose of avoiding contact with a shield case whose dimensional variations are large, and also, a clearance for avoiding contact with division means such as the dicing blade need not be provided in a portion outside the shield case. Thus, a smaller size and lower profile of the entire electronic circuit unit can be achieved. Furthermore, since the thickness of the shield layer is made much thinner than the plate thickness of the shield case, this is advantageous for achieving a smaller size and lower profile electronic circuit unit.

In the electronic circuit unit of such a configuration, preferably, the columnar conductive section is formed by dividing a through hole into which a conductive material is filled. As a result, in the dividing step for obtaining a large number of electronic circuit units from a large-area substrate, undesired cracks are not likely to occur in the columnar conductive section, and the reliability of the conduction between the shield layer and the grounding pattern is improved.

In the electronic circuit unit of such a configuration, preferably, the laminate is rectangular in plan view, and the columnar conductive sections are provided at the four corners of the laminate. As a result, a large number of electronic circuit units can be obtained efficiently from the large-area substrate, and the columnar conductive section can be formed without reducing the space factor of the electronic circuit unit.

In the electronic circuit unit of such a configuration, preferably, the insulating layer is formed by heat-crimping a prepreg material in a semi-cured state. As a result, an insulating layer which is thin, which has high insulation characteristics, and whose surface is flat can be formed easily. In this case, if the circuit substrate is a multilayer substrate which is layered by using, as a bonding layer, the same prepreg material as the insulating layer, since the same material can be utilized, manufacturing management becomes easy, and this is advantageous for reducing the cost.

To achieve the second object, in another aspect, the present invention provides a method of manufacturing an electronic circuit unit, the method including: an electronic component mounting step of mounting electronic components to each component mounting area on a large-area substrate having on one side thereof a large number of component mounting areas which are divided into a lattice form, a wiring pattern being formed in each component mounting area, and having a grounding pattern formed on the other side thereof; an insulating layer crimping step of, after the electronic component mounting step, layering an insulating layer on the one side of the large-area substrate and crimping the insulating layer onto the large-area substrate in a state in which the wiring pattern and the electronic components are covered; a shield layer forming step of, after the insulating layer crimping step, forming a shield layer formed of a conductive material on the top surface of the insulating layer; a through-hole forming step of, after the shield layer forming step, forming a large number of through holes in a large-area laminate formed in such a manner that the large-area substrate and the insulating layer are formed integrally so as to cause the grounding pattern and the shield layer to conduct with each other; and a dividing step of, after the through-hole forming step, dividing the large-area laminate for each of the component mounting areas so as to obtain a large number of individual electronic circuit units, wherein, in the dividing step, the through hole is divided for each electronic circuit unit.

When the electronic circuit unit is manufactured in this manner, since the electronic components can be shielded by the shield layer formed of a metal foil, etc., formed on the insulating layer, it is not necessary to mount a shield case made of a metal plate in each of the electronic circuit units, a large number of which is obtained. Therefore, it is not necessary to provide a wider clearance for avoiding contact with a shield layer having large dimensional variations around the electronic components mounted in the electronic circuit unit, and also, it is not necessary to provide a clearance for avoiding contact with the dividing means such as a dicing blade outside the shield case. Thus, a smaller size and lower profile electronic circuit unit can be achieved. Furthermore, since the thickness of the shield layer can be made much thinner than the plate thickness of the shield case, this is also advantageous for achieving a smaller size and lower profile electronic circuit unit.

In such a method of manufacturing an electronic circuit unit, in the shield layer forming step, preferably, the shield layer is patterned in a shape corresponding to the component mounting area. As a result, since the section between adjacent component mounting areas can be made to be a straight-line-shaped area where a shield layer does not exist, the shield layer need not be cut in the dividing step, and therefore, there is no risk in that burrs occur in the shield layer.

In such a method of manufacturing an electronic circuit unit, in the through-hole forming step, preferably, the through holes are formed at positions corresponding to the four corners of the component mounting area. As a result, it is possible to efficiently obtain a large number of electronic circuit units from a large-area substrate, and the through holes can be formed without reducing the space factor.

In such a method of manufacturing an electronic circuit unit, between the through-hole forming step and the dividing step, preferably, a through-hole filling step of filling a conductive material in each of the through holes is added. As a result, undesired cracks are not likely to occur in the dividing step, and the reliability of the conduction between the shield layer and the grounding pattern is improved.

In such a method of manufacturing an electronic circuit unit, preferably, the insulating layer is formed by heat-crimping a prepreg material in a semi-cured state. As a result, an insulating layer which is thin, which has high insulation characteristics, and whose surface is flat can be formed easily. In this case, if the large-area substrate is a multilayer substrate which is layered by using, as a bonding layer, the same prepreg material as the insulating layer, since the same material can be utilized, manufacturing management becomes easy, and this is advantageous for reducing the cost.

In the electronic circuit unit of the present invention, an insulating layer formed of a prepreg material, etc., is layered and crimped onto the circuit substrate, and the shield layer formed of a metal foil, etc., formed on the insulating layer is made to conduct with the grounding pattern via the columnar conductive section. Therefore, a shield case, made of a metal plate, having large dimensional variations and having a large plate thickness can be omitted, and thus, a smaller size and lower profile of the entire electronic circuit unit can be easily achieved.

The method of manufacturing an electronic circuit unit according to the present invention is such that an insulating layer formed of a prepreg material, etc., is layered and crimped onto a large-area substrate on which electronic components are mounted, and a shield layer formed of a metal foil, etc., which is formed on the insulating layer, is made to conduct with a grounding pattern via a through hole, after which a large number of individual electronic circuit units are obtained by dividing the large-area substrate into a lattice shape. Therefore, it is not necessary to mount in each electronic circuit unit a shield case, made of a metal plate, having large dimensional variations and a large plate thickness, and thus, an electronic circuit unit for which a smaller size and a lower profile can be easily achieved can be manufactured efficiently.

### BRIEF DESCRIPTION OF THE DRAWINGS

FIG. 1 is an illustration showing the cross section of an electronic circuit unit according to an embodiment of the present invention;

FIG. 2 is an exploded perspective view showing the electronic circuit unit;

FIG. 3 is a perspective view showing the bottom of the electronic circuit unit;

FIG. 4 is an illustration showing a large-area substrate preparation step when the electronic circuit unit is manufactured;

FIG. 5 is an illustration showing an electronic component mounting step when the electronic circuit unit is manufactured;

FIG. 6 is an illustration showing an insulating layer crimping step when the electronic circuit unit is manufactured;

FIG. 7 is an illustration showing a shield layer forming step when the electronic circuit unit is manufactured;

FIG. 8 is an exploded perspective view corresponding to the shield layer forming step in FIG. 7;

FIG. 9 is an illustration showing a through-hole forming step when the electronic circuit unit is manufactured;

FIG. 10 is an illustration showing a through-hole filling step when the electronic circuit unit is manufactured;

FIG. 11 is an illustration showing a dividing step when the electronic circuit unit is manufactured;

FIG. 12 is a perspective view showing a conventional electronic circuit unit; and

FIG. 13 is a process chart of manufacturing the conventional electronic circuit unit.

### DESCRIPTION OF THE PREFERRED EMBODIMENTS

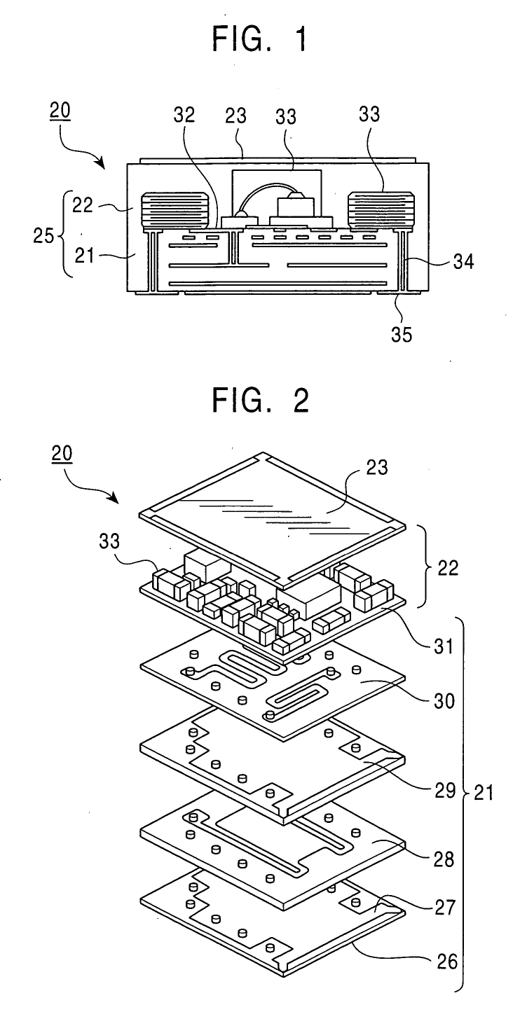

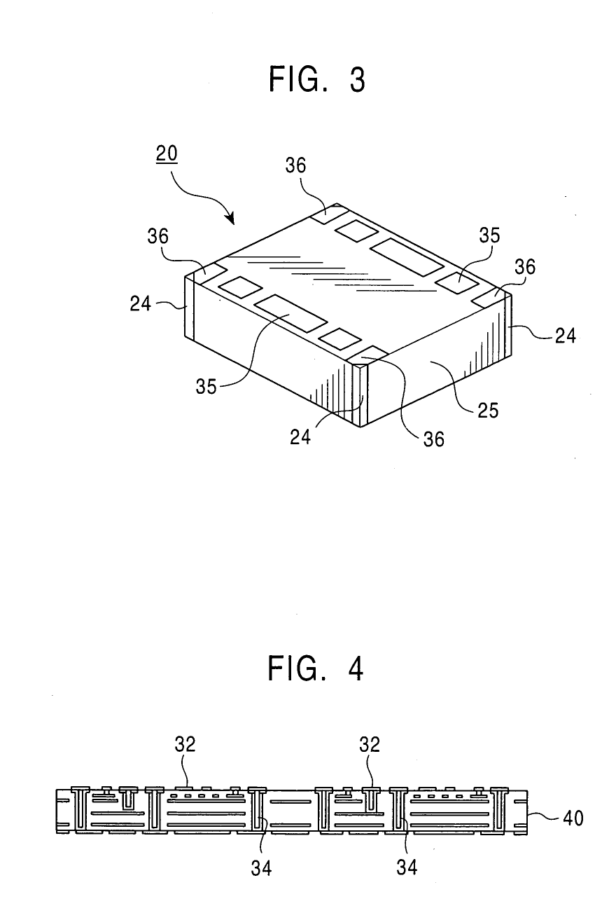

An embodiment of the present invention will now be described below with reference to the drawings. FIG. 1 is an illustration showing the cross section of an electronic circuit unit according to an embodiment of the present invention. FIG. 2 is an exploded perspective view showing the electronic circuit unit. FIG. 3 is a perspective view showing the bottom of the electronic circuit unit. FIGS. 4 to 11 are process charts of manufacturing the electronic circuit unit.

An electronic circuit unit 20 shown in FIGS. 1 to 3 is, for example, a voltage-controlled oscillator (VCO) which is rectangular in plan view. The electronic circuit unit 20 mainly includes a circuit substrate 21 which is a multilayer substrate, an insulating layer 22 which is layered and crimped onto a component mounting side 31 of the circuit substrate 21, and a shield layer 23 formed on the insulating layer 22. Columnar conductive sections 24 which extend in the height direction along the side wall of a laminate 25 are formed at the four corners of the laminate 25 which is formed in such a manner that the circuit substrate 21 and the insulating layer 22 are formed integrally. This columnar conductive section 24 is formed by dividing a through hole 51 (to be described later) into four portions, and the shield layer 23 conducts, via the columnar conductive section 24, with a grounding pattern 36 formed at the four corners of the bottom of the circuit substrate 21. Although not shown in FIGS. 1 and 2, the surface of the shield layer 23 is covered with a resist layer 37 (see FIGS. 9 to 11).

The circuit substrate 21 is a multilayer substrate such as that shown in FIG. 2, and includes a terminal electrode layer 26, a first ground layer 27, a resonance element wiring layer 28, a second ground layer 29, a tuning element wiring layer 30, and an electronic component mounting layer (component mounting side) 31 in this sequence from the bottom layer. These layers 26 to 31 are layered by using a prepreg material as a bonding layer. This prepreg material is such that, for example, a glass cloth is impregnated with an epoxy resin. By performing heat-crimping core materials of two opposing layers with a semi-cured prepreg material being provided in between, the core materials can be bonded while maintaining the insulation state. As shown in FIGS. 1 and 3, various electronic components 33, such as chip capacitors and semiconductors, which are soldered to the land portion of a wiring pattern 32, are mounted on the top surface (the component mounting side 31) of the circuit substrate 21. The wiring pattern 32 is connected, via an inside through hole 34, to an electrode pattern 35 such as an input/output terminal provided on the bottom (the terminal electrode layer 26) of the circuit substrate 21.

The insulating layer 22 is formed in such a manner that the semi-cured prepreg material is layered on the component mounting side 31 of the circuit substrate 21 and is heat-crimped. By appropriately selecting the thickness (the number) of the prepreg materials to be used, the surface of the insulating layer 22 by which the wiring pattern 32 and the electronic components 33 are covered can be made flat by applying pressure. The prepreg material, which is the material for the insulating layer 22, is the same as the prepreg material used as the bonding material in the circuit substrate 21 which is a multilayer substrate. The shield layer 23 is formed in such a manner that plating of a copper foil, etc., is applied to the insulating layer 22. The four corners of the shield layer 23 are connected to the upper ends of the columnar conductive sections 24.

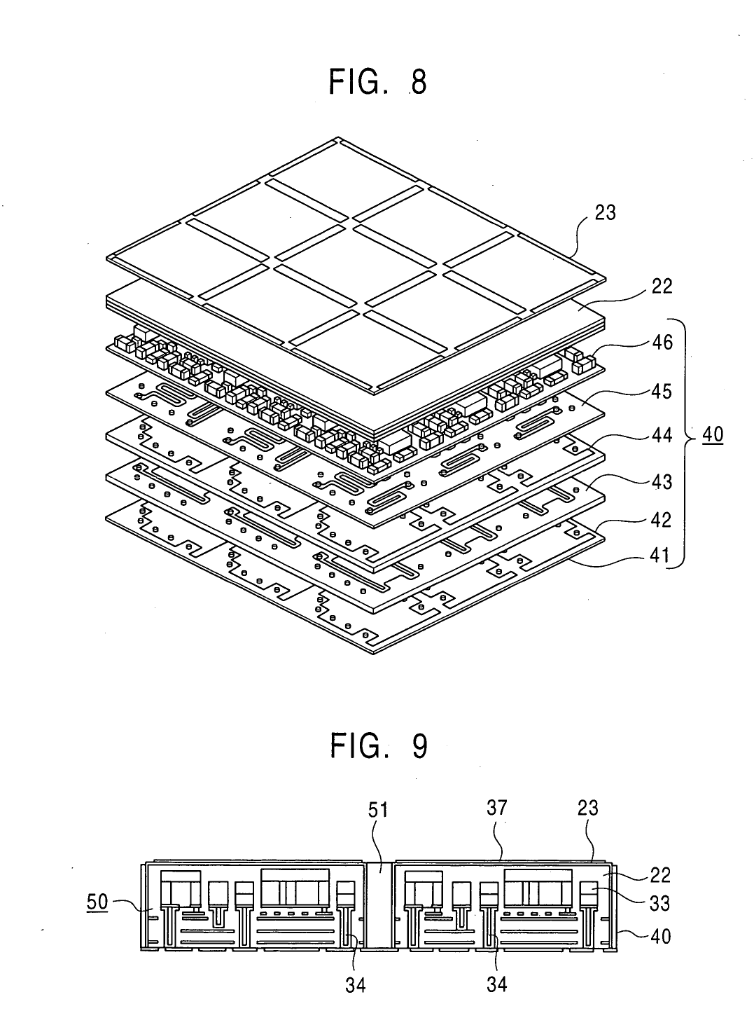

The method of manufacturing the electronic circuit unit 20 configured in this manner will now be described mainly with reference to FIGS. 4 to 11. First, as shown in FIG. 4, a large-area substrate 40 on which the wiring pattern 32, a through hole 34, etc., corresponding to a large number of electronic circuit units 20, are formed is prepared (the large-area substrate preparation step). The large-area substrate 40 is a multilayer substrate such as that shown in FIG. 8, and includes a large-area terminal electrode layer 41, a first large-area ground layer 42, a large-area resonance element wiring layer 43, a second large-area ground layer 44, a large-area tuning element wiring layer 45, and a large-area electronic component mounting layer 46 in this sequence from the bottom layer. These layers 41 to 46 are layered by using a prepreg material as a bonding layer. The large-area electronic component mounting layer 46, which is the topmost layer, is divided into a large number of component mounting areas by boundary lines in a lattice shape extending vertically and horizontally, and each component mounting area corresponds to one electronic circuit unit 20. Furthermore, in the large-area terminal electrode layer 41 which is the bottommost layer (bottom), the grounding pattern 36 and the electrode pattern 35 are formed.

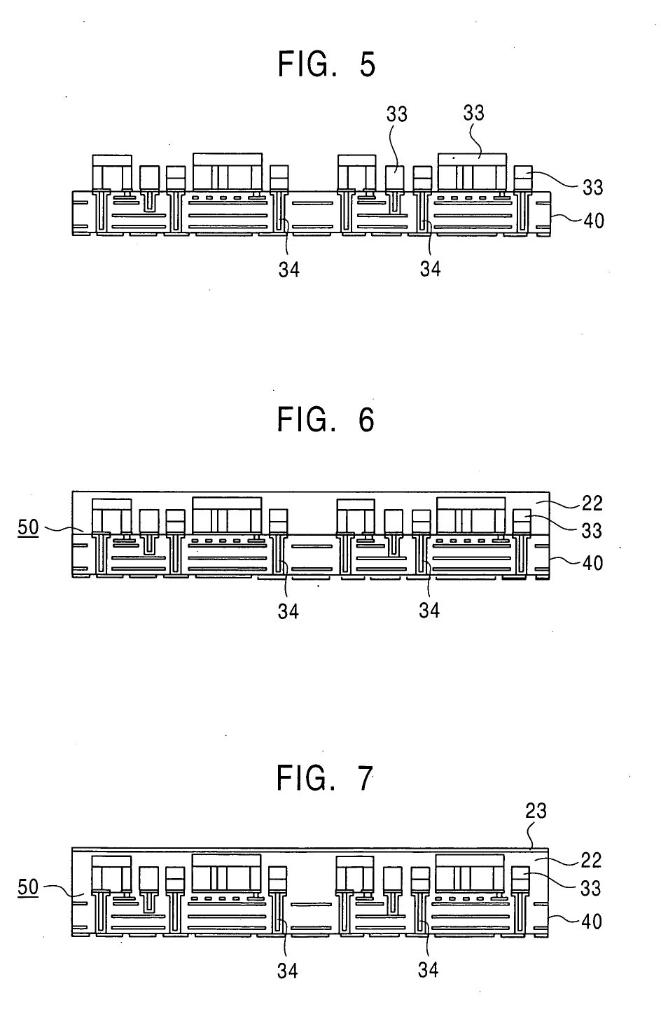

Thereafter, as shown in FIG. 5, on the top surface (the large-area electronic component mounting layer 46) of the large-area substrate 40, electronic components 33, such as chip capacitors and semiconductors, corresponding to a large number of electronic circuit units 20, are mounted (the electronic component mounting step). That is, cream solder is applied to the land portion of the wiring pattern 32 formed in each component mounting area, and various electronic components 33 are mounted on this cream solder, after which the large-area substrate 40 is conveyed to a reflow furnace, whereby these electronic components 33 are soldered.

In the next step, by layering a semi-cured prepreg material on the top surface of the large-area substrate 40 and by heating and applying pressure thereto, as shown in FIG. 6, the prepreg material is layered and crimped onto the large-area substrate 40, and the insulating layer 22 by which the wiring pattern 32 and the electronic components 33 are covered is formed (the insulating layer crimping step). The prepreg material, which is the material for the insulating layer 22, is the same as the prepreg material used in the large-area substrate 40. Reference numeral 50 in FIG. 6 denotes a large-area laminate formed in such a manner that the large-area substrate 40 and the insulating layer 22 are formed integrally in this manner.

Thereafter, as shown in FIG. 7, a plating process is performed on the top surface of the insulating layer 22 so as to form the shield layer 23 made of a copper foil, etc. (the shield layer forming step). Since this shield layer 23 is patterned in a shape shown in FIG. 8, that is, a shape corresponding to each component mounting area, the shield layer 23 is not formed in the lattice-shaped straight-line portion corresponding to the boundary line, except the intersection.

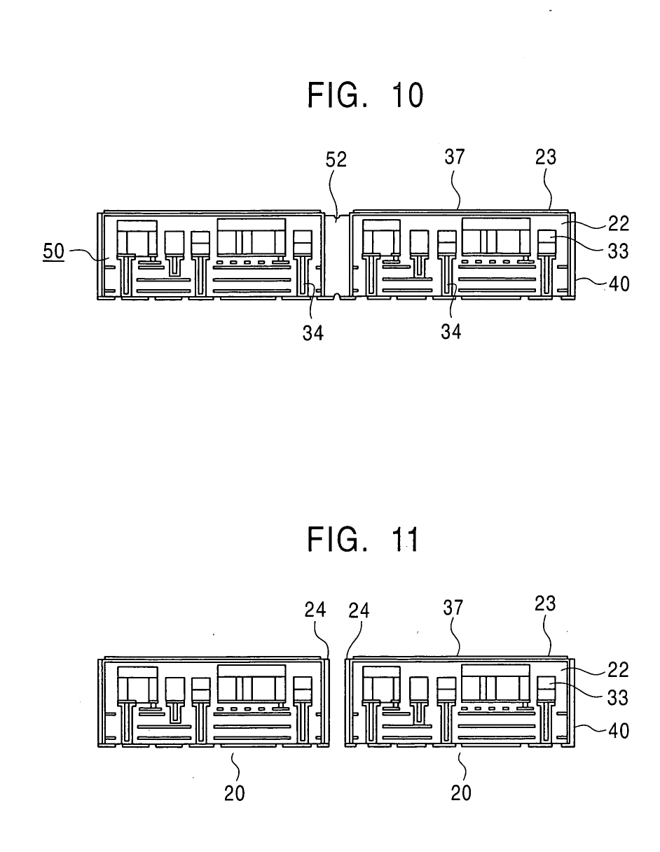

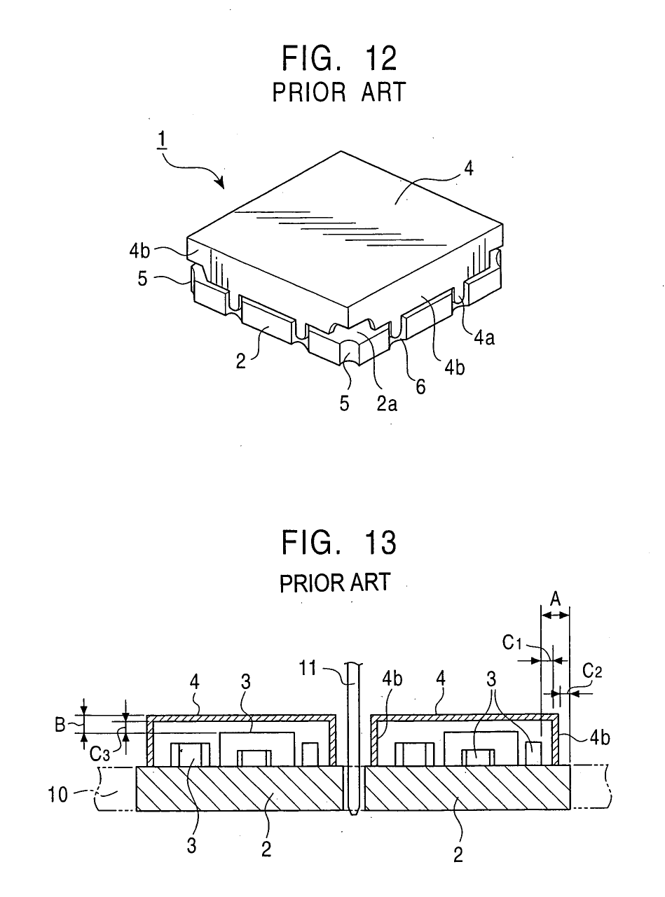

Next, as shown in FIG. 9, a large number of through holes 51 is formed in the large-area laminate 50 formed in such a manner that the large-area substrate 40 and the insulating layer 22 are formed integrally (the through-hole forming step). These through holes 51 are provided at the positions corresponding to the four corners (the intersections) of each component mounting area divided into a lattice shape, and the upper end of each through hole 51 is connected to the shield layer 23. Furthermore, the lower end of each through hole 51 is connected to the grounding pattern 36 formed on the bottom of the large-area substrate 40. Therefore, the shield layer 23 conducts with the grounding pattern 36 via the through hole 51. This makes it possible to measure the frequency characteristics for each electronic circuit unit 20. Then, after frequency adjustment is performed for each electronic circuit unit 20 in the state of the large-area laminate 50, the resist layer 37 is formed on the surface of the shield layer 23, and further, each of the through holes 51 is filled with a conductive material 52 such as a silver paste, as shown in FIG. 10 (the through-hole filling step).

Eventually, by cutting the large-area laminate 50 along the boundary line by using a dicing blade, etc., as shown in FIG. 11, the large-area laminate 50 is divided for each component mounting area so as to obtain a large number of electronic circuit units 20 (the dividing step). At this time, since each through hole 51 filled with the conductive material 52 is divided into four portions to form the columnar conductive sections 24, the columnar conductive sections 24 are provided at the four corners of the electronic circuit unit 20 which is rectangular in plan view. When the large-area laminate 50 is to be divided into individual electronic circuit units 20 in this manner, each electronic circuit unit 20 is not made apart by pasting in advance an adhesive tape (not shown), and performance testing of the individual electronic circuit units 20 is performed, after which the adhesive tape is removed.

As described above, in the electronic circuit unit 20 according to this embodiment, the shield layer 23 made of a copper foil, etc., is provided on the insulating layer 22 which is layered and crimped onto the component mounting side 31 of the circuit substrate 21, and this shield layer 23 is made to conduct with the grounding pattern 36 via the columnar conductive section 24. Consequently, the electronic components 33 mounted on the component mounting side 31 are shielded by the shield layer 23, and thus shield cases made of a metal plate, whose dimensional variations are large, is not necessary. In the case of the shield case made of a metal plate, it is necessary to provide a wide clearance in the vicinity of a side wall section. However, in the case of the electronic circuit unit 20, even if the spacing between the electronic components 33 positioned in the outermost peripheral portion of the component mounting side 31 and the side surface of the insulating layer 22 is small, there is no risk in that the reliability is deteriorated. As a result, setting to outer dimensions with a very small wasted clearance is possible, and a smaller size is achieved. Furthermore, since the shield layer 23 can be formed much thinner than the plate thickness of the shield case made of a metal plate, a lower profile electronic circuit unit 20 is also achieved.

Since the columnar conductive sections 24 are provided at the four corners in such a manner as to be rectangular in plan view, a large number of electronic circuit units 20 can be obtained from the large-area substrate 40, and also, the columnar conductive section 24 can be formed without reducing the space factor of the electronic circuit unit 20. Since the columnar conductive sections 24 are such that the through hole 51 into which the conductive material 52 is filled is divided into four portions, undesired cracks are not likely to occur in the columnar conductive section 24 in the step of dividing the large-area substrate 40, and the reliability of the conduction between the shield layer 23 and the grounding pattern 36 is high.

Since the insulating layer 22 of the electronic circuit unit 20 is formed by heat-crimping a semi-cured prepreg material, the insulating layer 22 which is thin, which has high insulation characteristics, and whose surface is flat can be formed easily. Moreover, since the prepreg material, which is a material for the insulating layer 22, is the same as the prepreg material used as the bonding layer of the circuit substrate 21 (the large-area substrate 40) which is a multilayer substrate, the same material can be utilized, manufacturing management becomes easy, and the cost does not increase.

In this embodiment, in the shield layer forming step shown in FIG. 7, the shield layer 23 is patterned in a shape corresponding to each component mounting area, and the section between adjacent component mounting areas can be made to be a straight-line-shaped area where a shield layer does not exist. As a result, the shield layer 23 need not be cut in the subsequent dividing step, and therefore, there is no risk in that burrs occur in the shield layer 23.

1. An electronic circuit unit comprising:
a circuit substrate having electronic components mounted on one side thereof on which a wiring pattern is formed;
an insulating layer which is layered and crimped onto said one side of the circuit substrate so as to cover said wiring pattern and said electronic components; and
a shield layer, formed of a conductive material, which is formed on the insulating layer,
wherein a grounding pattern formed on a side opposite to said one side of the circuit substrate and said shield layer are made to conduct with each other via a columnar conductive section provided on a side wall of a laminate formed in such a manner that said circuit substrate and said insulating layer are formed integrally.

2. The electronic circuit unit according to claim 1, wherein said columnar conductive section is formed by dividing a through hole into which a conductive material is filled.

3. The electronic circuit unit according to claim 1, wherein said laminate is rectangular in plan view, and said columnar conductive sections are provided at four corners of the laminate.

4. The electronic circuit unit according to claim 1, wherein said insulating layer is formed by heat-crimping a prepreg material in a semi-cured state.

5. The electronic circuit unit according to claim 4, wherein said circuit substrate is a multilayer substrate which is layered by using, as a bonding layer, the same prepreg material as said insulating layer.

6. A method of manufacturing an electronic circuit unit, said method comprising:
an electronic component mounting step of mounting electronic components to each component mounting area on a large-area substrate having on one side thereof a large number of component mounting areas which are divided into a lattice form, a wiring pattern being formed in each component mounting area, and having a grounding pattern formed on the other side thereof;
an insulating layer crimping step of, after said electronic component mounting step, layering an insulating layer on said one side of said large-area substrate and crimping the insulating layer onto the large-area substrate in a state in which said wiring pattern and said electronic components are covered;
a shield layer forming step of, after said insulating layer crimping step, forming a shield layer formed of a conductive material on a top surface of said insulating layer;
a through-hole forming step of, after said shield layer forming step, forming a large number of through holes in a large-area laminate formed in such a manner that said large-area substrate and said insulating layer are formed integrally so as to cause said grounding pattern and said shield layer to conduct with each other; and
a dividing step of, after said through-hole forming step, dividing said large-area laminate for each of said component mounting areas so as to obtain a large number of individual electronic circuit units,
wherein, in said dividing step, said through hole is divided for each electronic circuit unit.

7. The method of manufacturing an electronic circuit unit according to claim 6, wherein, in said shield layer forming step, said shield layer is patterned in a shape corresponding to said component mounting areas.

8. The method of manufacturing an electronic circuit unit according to claim 6, wherein, in said through-hole forming step, said through holes are formed at positions corresponding to four corners of said component mounting area.

9. The method of manufacturing an electronic circuit unit according to claim 6, further comprising a through-hole filling step of filling a conductive material in each of said through holes between the through-hole forming step and the dividing step.

10. The method of manufacturing an electronic circuit unit according to claim 6, wherein said insulating layer is formed by heat-crimping a prepreg material in a semi-cured state.

11. The method of manufacturing an electronic circuit unit according to claim 10, wherein said large-area substrate is a multilayer substrate which is layered by using, as a bonding layer, the same prepreg material as said insulating layer.
